(19) United States
(12) Patent Application Publication
(10) Pub. No.: US 2022/0298786 A1
(43) Pub. Date: Sep. 22, 2022

(54) INTEGRATED MODULAR SMART FACADE SYSTEM

(71) Applicant: IntEGrA D&C Inc., Siheung-si (KR)

(72) Inventors: Brian Baewon KOH, Gunpo-si (KR); Sang Hyun JEON, Hanam-si (KR)

(73) Assignee: IntEGrA D&C Inc.

(21) Appl. No.: 17/370,116

(22) Filed: Jul. 8, 2021

(30) Foreign Application Priority Data
Mar. 22, 2021 (KR) 10-2021-0036801

(51) Int. Cl. E04B 2/96; F24F 3/00; F28D 20/02; F24F 3/16; F24F 3/14; H01L 35/32; H02S 20/26

(52) U.S. Cl. CPC E04B 2/96; F24F 3/001; F28D 20/02; F24F 3/16; F24F 3/14; H01L 35/32; H02S 20/26; F24F 2221/17; F24F 2003/144

(57) ABSTRACT

Disclosed is an integrated modular smart facade system that has improved energy efficiency and comfort in an indoor environment and that is easy to install, and more particularly an integrated modular smart facade system including a curtain wall frame (10), an air conditioning unit (20) located in a hollow portion (4) of the curtain wall frame (10), a window unit (30) located in an opening (3) of the curtain wall frame (10), and an electricity production unit (40) located at a portion of an outer wall of the air conditioning unit (20).

### REFERENCE TO RELATED APPLICATIONS

This application claims the priority benefit of Korean Patent Application No. 10-2021-0036801 filed on Mar. 22, 2021 the entire contents of which are incorporated herein by reference.

### FIELD OF THE INVENTION

The present invention relates to an integrated modular smart facade system with extensibility including optimal indoor environment control technology, and more particularly to an integrated modular smart facade system including an electricity production unit, an air conditioning unit, and a window unit for heat insulation and shading, which are configured as unit devices capable of being separated therefrom and coupled thereto, wherein the integrated modular smart facade system is linked with a control system having artificial-intelligence-based active control technology applied thereto, whereby it is possible for the integrated modular smart facade system to improve energy efficiency of a building and to minimize unbalance in an indoor thermal environment while having extensibility.

### BACKGROUND OF THE INVENTION

In general, a building has equipment for cooling, heating, and ventilation. A machinery compartment is installed in the building in order to perform central management, and equipment in the machinery compartment, which is installed in a basement of the building, supplies heat to respective spaces in the building via pipes. For the above method, construction is complicated, heat must be conveyed, and various construction materials necessary to process the load of external air are introduced in large quantity. For a large-scale building, therefore, heat loss is increased during conveyance of heat.

An outer wall and a window of the building protect an indoor environment from external weather, such as rain, snow, and typhoons, and provide natural light and views. However, the space of an outer circumferential portion of the building adjacent to the outer wall and the window has a different environment from a warm environment in an inner circumferential portion of the building due to the effect of an external air environment transmitted through the outer wall and the window, whereby thermal discomfort occurs, and conventional central air conditioning equipment has a limitation in solving this problem.

In particular, the window is a facade element to be essentially included, since it is possible to allow natural light to be introduced indoors and to secure indoor and outdoor views. In many cases, however, the window has lower thermal insulation than a wall or a roof, and therefore the window becomes a main cause of building energy loss. In addition, the window becomes a main heat loss path in winter and becomes an excess light introduction path in summer, and therefore the amount of energy necessary to cool and heat the building greatly depends on window design.

In connection therewith, Patent Document 1 discloses a photovoltaic power generation and solar heat collection complex system including a solar panel configured to produce electricity from incident solar light, a solar heat collection module configured to collect solar heat, and a support member and a pivot shaft configured to allow the solar panel and the solar heat collection module to be rotated. In Patent Document 1, however, generation of electricity during the night is difficult, since the system is configured to generate electricity and to collect heat using solar light and solar heat during the day.

Patent Document 2 discloses a cooling, heating, and ventilation system configured such that a PV module including a solar cell panel, among PVT modules installed outside a building, produces electricity from solar light and stores the produced electricity in an energy storage system and such that a heat collection module installed under the PV module to obtain heat from solar light transmits heated water to a hot water tank or a heat pump. In Patent Document 2, however, elements constituting the cooling, heating, and ventilation system are located on the roof, the outer wall, and the interior of the building in a dispersed state, whereby installation of the cooling, heating, and ventilation system is complicated and operation of the cooling, heating, and ventilation system during the night is difficult.

As can be seen from the above description, exterior building module technology capable of improving energy efficiency, providing a comfortable indoor thermal environment, being easily adjusted in size depending on installation position thereof, changing and combining components as needed, and achieving easy installation has not yet been presented.

(Patent Document 0001) Korean Registered Patent 2081890 (“Patent Document 1”)

(Patent Document 0002) Korean Patent Application Publication No. 2018-0117267 (“Patent Document 2”)

### SUMMARY OF THE INVENTION

The present invention has been made in view of the above problems, and it is an object of the present invention to provide an integrated modular smart facade system configured such that an electricity production unit, an air conditioning unit, and a window unit for heat insulation and shading are changed in construction and combined with each other to change the size of the integrated modular smart facade system, as needed, such that the integrated modular smart facade system is easy to install, and such that the integrated modular smart facade system is detachably attached to a building.

In order to accomplish the above object, an integrated modular smart facade system according to the present invention includes a curtain wall frame (10) that forms a main structure, an air conditioning unit (20) located in a hollow portion (4) of the curtain wall frame (10), a window unit (30) located in an opening (3) of the curtain wall frame (10), and an electricity production unit (40) located at a portion of an outer wall of each of the curtain wall frame (10) and the air conditioning unit (20).

In the integrated modular smart facade system according to the present invention, the electricity production unit (40) may include one or more power generation units.

In the integrated modular smart facade system according to the present invention, each of the power generation units may include a solar energy power generation unit (410) and/or a thermoelectric element power generation unit (420).

In the integrated modular smart facade system according to the present invention, the electricity production unit (40) may further include a heat storage unit (430).

In the integrated modular smart facade system according to the present invention, the heat storage unit (430) may be made of a phase change material including a thermal conductor.

The integrated modular smart facade system according to the present invention may further include a heat exchanger (223) and a heat pump (222) located in the air conditioning unit (20), wherein air discharged from the heat exchanger (223) may be used as a heat source of the heat pump (222).

The integrated modular smart facade system according to the present invention may further include an air purification and sterilization unit located in the air conditioning unit (20), wherein the air purification and sterilization unit may be connected to the heat exchanger and the heat pump.

The integrated modular smart facade system according to the present invention may further include a dehumidifier (224) located in the air conditioning unit (20), wherein the dehumidifier (224) may be connected to the heat pump (222).

The integrated modular smart facade system according to the present invention may further include a heat collection unit (60) located at a portion of the outer wall of the air conditioning unit (20), wherein air discharged from the heat collection unit (60) may be used as a heat source of the heat pump (222) and the dehumidifier (224).

The integrated modular smart facade system according to the present invention may be used as a unit module, and may be vertically and horizontally coupled to a plurality of modular facade systems.

The integrated modular smart facade system according to the present invention may further include a vertical exhaust and ventilation device (not shown) located at the upper surface of a coupled module in order to adjust pressure and/or temperature in a hollow layer.

In the integrated modular smart facade system according to the present invention, devices including controllers, such as the heat exchanger (223), the heat pump (222), a shading unit (70), the electricity production unit (40), and the heat collection unit (60), and sensors (not shown) may be connected to a control system having active control technology applied thereto.

The present invention may be provided as various combinations of the above solutions.

As is apparent from the above description, an integrated modular smart facade system according to the present invention has advantages in that component units constituting the integrated modular smart facade system are combined with each other depending on the installation position thereof, whereby it is possible to adjust the size of the integrated modular smart facade system, and in that modules manufactured at a factory are installed at a building, whereby it is possible to simplify on-site work.

Device units constituting the integrated modular smart facade system according to the present invention are easy to change in disposition and are variously combined with each other as needed, whereby it is possible to improve usability of the system.

Device units constituting each module according to the present invention are configured to be easily attached thereto and detached therefrom, whereby maintenance is easy during an administration process.

It is possible to operate the integrated modular smart facade system according to the present invention both during the day and during the night, and it is possible to improve energy efficiency and comfort in an indoor environment through the system.

### BRIEF DESCRIPTION OF THE DRAWINGS

FIG. 1 is a perspective view of an integrated modular smart facade system according to a first embodiment of the present invention.

FIG. 2 is an exploded perspective view of the integrated modular smart facade system according to the first embodiment of the present invention.

FIG. 3 is a perspective view of a curtain wall frame according to a first embodiment of the present invention.

FIG. 4 is an external front view of the integrated modular smart facade system according to the first embodiment of the present invention.

FIG. 5 is a sectional view taken along C1-C1′ of FIG. 4.

FIG. 6(a1) is a sectional view taken along A1-A1′ of FIG. 4, and FIG. 6(b1) is a sectional view taken along B1-B1′ of FIG. 4.

FIG. 7(c) is a side sectional view of an electricity production unit according to a first embodiment of the present invention, and FIG. 7(d) is a side sectional view of a glass unit.

FIG. 8 is an external front view of an integrated modular smart facade system according to a second embodiment of the present invention.

FIG. 9 is a sectional view taken along C2-C2′ of FIG. 8.

FIG. 10(a2) is a sectional view taken along A2-A2′ of FIG. 8, and FIG. 10(b2) is a sectional view taken along B2-B2′ of FIG. 8.

FIG. 11 is an external front view of an integrated modular smart facade system according to a third embodiment of the present invention.

FIG. 12(a3) is a sectional view taken along A3-A3′ of FIG. 11, and FIG. 12(b3) is a sectional view taken along B3-B3′ of FIG. 11.

### DETAILED DESCRIPTION OF THE INVENTION

Now, preferred embodiments of the present invention will be described in detail with reference to the accompanying drawings such that the preferred embodiments of the present invention can be easily implemented by a person having ordinary skill in the art to which the present invention pertains. In describing the principle of operation of the preferred embodiments of the present invention in detail, however, a detailed description of known functions and configurations incorporated herein will be omitted when the same may obscure the subject matter of the present invention.

In addition, the same reference numbers will be used throughout the drawings to refer to parts that perform similar functions or operations. In the case in which one part is said to be connected to another part in the specification, not only may the one part be directly connected to the other part, but also, the one part may be indirectly connected to the other part via a further part.

In the present application, it should be understood that the terms “comprises,” “has,” or “includes,” etc. specify the presence of features, integers, steps, operations, components, parts, or combinations thereof described in the specification, but do not preclude the presence or addition of one or more other features, integers, steps, operations, components, parts, or combinations thereof.

In addition, that a certain element is included does not mean that other elements are excluded, but means that such elements may be further included unless mentioned otherwise.

It should be understood that when a component is referred to as being “connected to” or “coupled to” another component, it may be directly connected to or coupled to another component, or intervening components may be present therebetween. In contrast, it should be understood that when a component is referred to as being “directly connected to” or “directly coupled to” another component, there are no intervening components present. Other terms that describe the relationship between components, such as “between” and “directly between” or “adjacent to” and “directly adjacent to,” are to be interpreted in the same manner.

In addition, all terms including technical or scientific terms have the same meanings as those generally understood by a person having ordinary skill in the art to which the present invention pertains, unless defined otherwise. Generally used terms, such as terms defined in a dictionary, should be interpreted as coinciding with the meanings of the related art from the context. Unless obviously defined in the present application, such terms are not to be interpreted as having ideal or excessively formal meanings.

Hereinafter, embodiments of the present invention will be described in detail with reference to the accompanying drawings. Same components in the drawings are denoted by the same reference numerals, and a duplicate description thereof will be omitted.

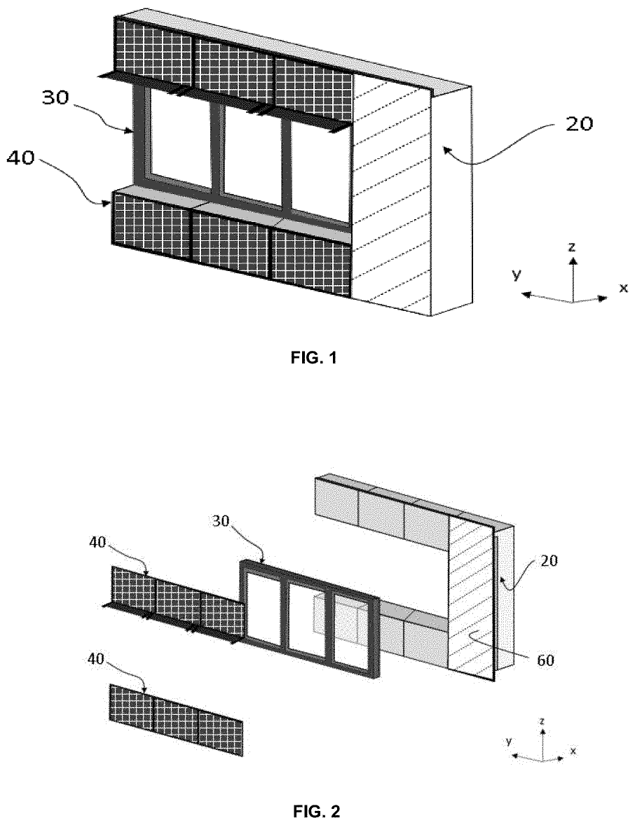

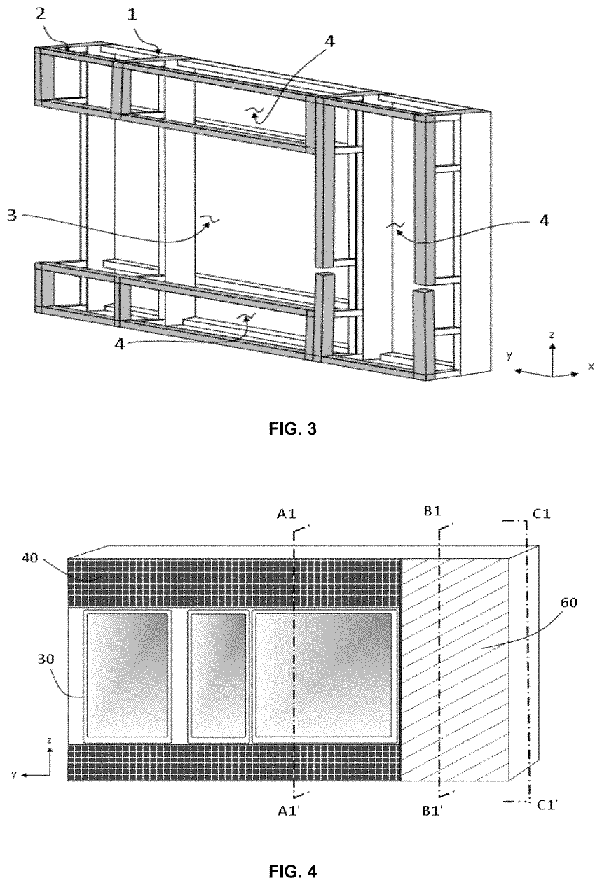

FIG. 1 is a perspective view of an integrated modular smart facade system according to a first embodiment of the present invention, FIG. 2 is an exploded perspective view of the integrated modular smart facade system according to the first embodiment of the present invention, and FIG. 3 is a perspective view of a curtain wall frame 10 according to a first embodiment of the present invention.

The integrated modular smart facade system according to the first embodiment of the present invention will be described with reference to FIGS. 1 to 3. The integrated modular smart facade system includes an air conditioning unit 20, a window unit 30, and an electricity production unit 40. In addition, the air conditioning unit 20, the window unit 30, and the electricity production unit 40 may be disposed at predetermined positions of the curtain wall frame 10.

The curtain wall frame 10 according to the first embodiment of the present invention may be configured to have a structure in which an inner layer 1 and an outer layer 2 are coupled to each other. Here, each of the inner layer 1 and the outer layer 2 may be constituted as the result of coupling between layer units (not shown), and each of the layer units may include a coupling member configured to be easily separated from or coupled to a layer unit adjacent thereto.

When the inner layer 1 and the outer layer 2 are coupled to each other, a hollow portion 4 may be defined therebetween. The inner layer 1 and the outer layer 2 may be located horizontally or vertically based on the ground, or may be configured to have a three-dimensional shape formed as the result of horizontal and vertical combinations. A wall surface (not shown) configured to wrap the outer surface of the inner layer 1 and the outer layer 2 that are coupled to each other may be further provided, and an opening 3 may be defined between the coupled layers.

The air conditioning unit 20 may be partially or entirely located in the hollow portion 4 of the curtain wall frame 10. The air conditioning unit 20 may be configured to have a quadrangular frame shape or a quadrangular frame shape having one open surface. Here, the air conditioning unit 20 may be provided with a partition wall, via which the air conditioning unit may be connected to a partition wall of a building or another modular system. The outer circumferential surface of the partition wall of the air conditioning unit 20 may be brought into tight contact with a wall of the building connected to the outer circumferential surface of the partition wall so as to be adjacent thereto or the inner circumferential surface of a partition wall of the other modular system. An additional coupling member and/or a sealing member may be further disposed in order to achieve tight contact therebetween.

The window unit 30 may be located in the opening 3 of the curtain wall frame 10, and the window unit 30 and the air conditioning unit 20 that are coupled to each other may be located in an inner space of the curtain wall frame 10.

The electricity production unit 40 may be disposed at an outer wall surface of the curtain wall frame 10, which faces outwards. The electricity production unit 40 may be disposed at a portion or the entirety of the outer wall surface of the curtain wall frame 10, which faces outwards, or may extend toward an outer wall surface of the building.

In addition, a heat collection unit 60 may be disposed at an outer wall surface of the air conditioning unit 20, which faces outwards. Here, the heat collection unit 60 is a device configured to collect solar heat. Heat collected by the heat collection unit 60 may heat air, and may supply the heated air to a heat pump 222 or a dehumidifier 224 or may be used for other heat supplies. The heat collection unit 60 may include a sensor (not shown) configured to sense the intensity of solar heat and a controller (not shown) electrically connected to the sensor, the controller being configured to control the operation of the heat collection unit 60. The controller may be configured as an automatic controller capable of performing automatic control based on the value of the sensor or a manual controller.

In FIG. 1, the integrated modular smart facade system is shown as having a quadrangular frame shape. However, it is obvious that the shape of the integrated modular smart facade system is not restricted as long as the integrated modular smart facade system is connected to the wall of the building or the other modular system so as to be integrated therewith.

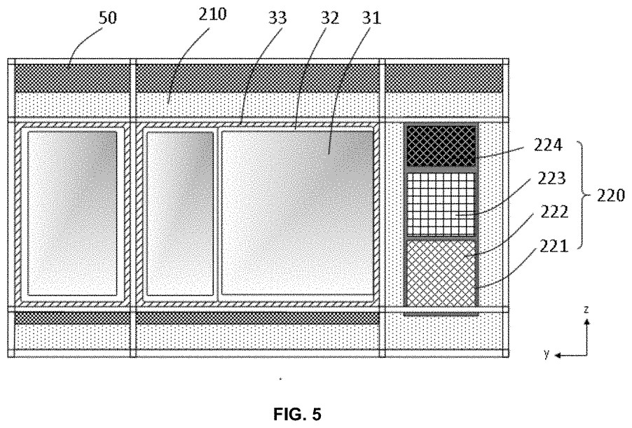

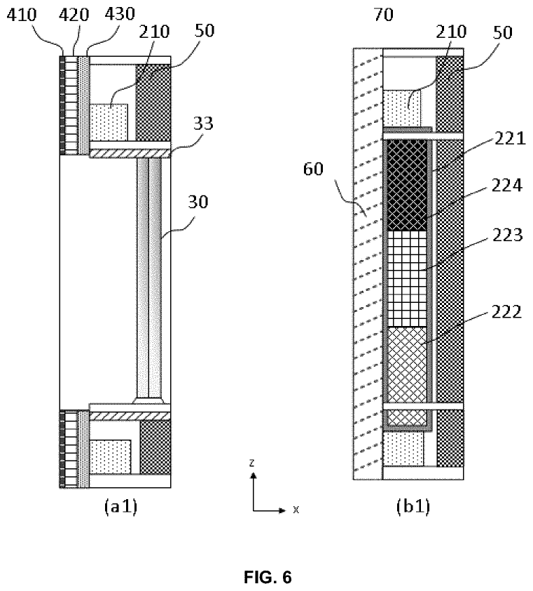

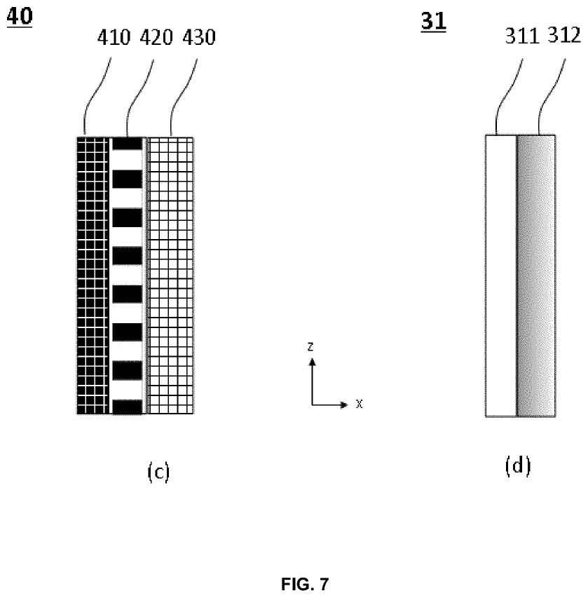

FIG. 4 is an external front view of the integrated modular smart facade system according to the first embodiment of the present invention, FIG. 5 is a sectional view of the integrated modular smart facade system taken along C1-C1′ of FIG. 4, FIG. 6(a1) is a sectional view taken along A1-A1′ of FIG. 4, FIG. 6(b1) is a sectional view taken along B1-B1′ of FIG. 4, FIG. 7(c) is a side sectional view of an electricity production unit according to a first embodiment of the present invention, and FIG. 7(d) is a side sectional view of a glass unit.

Referring to FIGS. 4 to 6, an air conditioning unit 20 according to a first embodiment of the present invention may include a duct unit 210 and an air treatment unit 220 disposed in the hollow portion 4 of the curtain wall frame 10. In addition, a heat insulation portion 50 may be disposed at an inner wall surface of the hollow portion 4 of the curtain wall frame 10, which is located so as to face the interior of the building, in order to reduce heat exchange between the hollow portion 4 of the curtain wall frame 10 and the interior of the building and to maintain a stable indoor thermal environment.

The air treatment unit 220 may include a heat pump 222, a heat exchanger 223, and a dehumidifier 224. Here, an elastic frame 221 may be provided at the outer surface of each of the heat pump 222, the heat exchanger 223, and the dehumidifier 224 or at a frame to which equipment is mounted. Specifically, the elastic frame 221 may be made of an elastic metamaterial, and may reduce vibration generated during operation of the air treatment unit 220.

The heat pump 222 may use air in the hollow portion 4 heated by heat generated by the electricity production unit 40 and air discharged from the heat exchanger 223 as a heat source. An air purification and sterilization unit (not shown) may be disposed at the connection region between the heat pump 222 and the heat exchanger 223 in order to remove contaminants and viruses in air supplied indoors. In addition, the air purification and sterilization unit may be connected to the heat exchanger and the heat pump.

The heat exchanger 223 may be connected to the heat pump 222. Specifically, the heat exchanger 223 may include a fan (not shown) installed at a heat exchanger case (not shown) and a heat exchange element (not shown) located in the case. The heat exchange element may include a phase change material (PCM) as an ingredient. Indoor air and external air may exchange heat with each other in the heat exchanger 223 and may then be supplied to the heat pump 222 again. The heat pump 222 may use the external air and the indoor air that have passed through the heat exchanger 223, whereby it is possible to heat or cool the air and to supply a necessary amount of heat indoors while reducing heat loss. This system has an advantage in that it is possible to secure the amount of ventilation and to reuse recirculated air, whereby it is possible to reduce heat loss, and therefore it is possible to reduce the amount of energy necessary for cooling and heating.

The heat exchanger 223 and the heat pump 222 may be linked with a building energy management system in order to effectively control an indoor warm environment and an air quality environment through active control thereof.

The dehumidifier 224, which is configured to remove excess moisture in air supplied from the outside, may be configured to use heated air discharged from an outdoor unit (not shown) of the heat pump 222 and supplied to the heat collection unit 60 so as to be further heated, whereby it is possible to reduce the amount of energy necessary during air dehumidification of the dehumidifier 224.

In the first embodiment of the present invention, the heat pump 222, the heat exchanger 223, and the dehumidifier 224 of the air treatment unit 220 are sequentially disposed. However, such a disposition may be changed depending on a required installation space and combination of equipment, and one or more components constituting the air treatment unit may be disposed in the air conditioning unit 20. In addition, the elastic frame 221 of the air treatment unit 220 may be manufactured so as to have an integrated shape. Alternatively, an individual elastic frame may be manufactured for each of the heat pump 222, the heat exchanger 223, and the dehumidifier 224, and the air treatment unit 220 may include a coupling member configured to couple and fix adjacent ones of the individual elastic frames to each other.

Next, a window unit 30 according to a first embodiment of the present invention will be described.

The window unit 30 may include smart glass 31 and a sash 32 configured to fix the smart glass 31. An anti-condensation member 33 may be located at the portion of the sash 32 of the window unit 30 that faces the wall surface of the curtain wall frame 10. Here, the anti-condensation member 33 may include a PCM.

As shown in FIG. 7(d), smart glass 31 according to a first embodiment of the present invention may include a glass layer 311 and a polarizing film 312 attached to the indoor side surface of the glass layer 311 in tight contact therewith. One or more polarizing films 312 may be attached to the glass layer 311 in an overlapping state in order to adjust the rate of irradiation of solar light radiated indoors and to block visible light. In addition, the glass layer 311 may be made of dual glass, and the polarizing film 312 may be located between two panes constituting the dual glass.

As shown in FIG. 7(c), the electricity production unit 40 according to the first embodiment of the present invention may include a solar energy power generation unit 410 and/or a thermoelectric element power generation unit 420. In addition, the solar energy power generation unit 410 may be of a photovoltaic power generation type.

The solar energy power generation unit 410 may include a rotary member (not shown) configured to be slidable forwards and rearwards relative to the outer wall surface of the building depending on the location of the sun. The rotary member may be sensed by the sensor and controlled by the controller in order to adjust the relative angle of the solar energy power generation unit 410.

The thermoelectric element power generation unit 420 may be located adjacent to the solar energy power generation unit 410, and may produce electricity using the difference in temperature between the solar energy power generation unit 410 and a heat storage unit 430.

Electricity produced by the solar energy power generation unit 410 according to the first embodiment of the present invention may be used as electricity necessary to operate the building, and electricity produced by the thermoelectric element power generation unit 420 may be used to operate sensor monitoring equipment of the integrated modular smart facade system. In addition, an electricity storage device (not shown) may be provided to store electricity produced by the electricity production unit 40, as needed.

In addition, the electricity production unit 40 may include a heat storage unit 430. As shown in FIG. 7(c), the heat storage unit 430 may be located adjacent to the surface of the thermoelectric element power generation unit 420 opposite the surface thereof adjacent to the solar energy power generation unit 410. It is possible to produce electricity using the difference in temperature between the solar energy power generation unit 410 and the heat storage unit 430 during the day, and it is also possible to produce electricity as the result of temperature inversion between the solar energy power generation unit 410 and the heat storage unit 430 due to a decrease in temperature of external air during the night.

Here, the heat storage unit 430 may include a phase change material (PCM) including a thermal conductor configured to absorb or discharge heat.

The air in the hollow portion affected by the heat pump 222, the heat exchanger 223, the air treatment unit 220, and the conditions of external air through a vertical exhaust and ventilation device (not shown) operated by a temperature increase and/or atmospheric pressure depending on whether the air is utilized, whereby it is possible to minimize the effect to the system that is operated.

Each component included in the integrated modular smart facade system according to the first embodiment of the present invention may constitute a unit module, disposition of the unit modules may be changed depending on the characteristics of installation positions and spaces, and the size of the integrated modular smart facade system may be easily changed depending on combination of the unit modules and disposition of the unit modules.

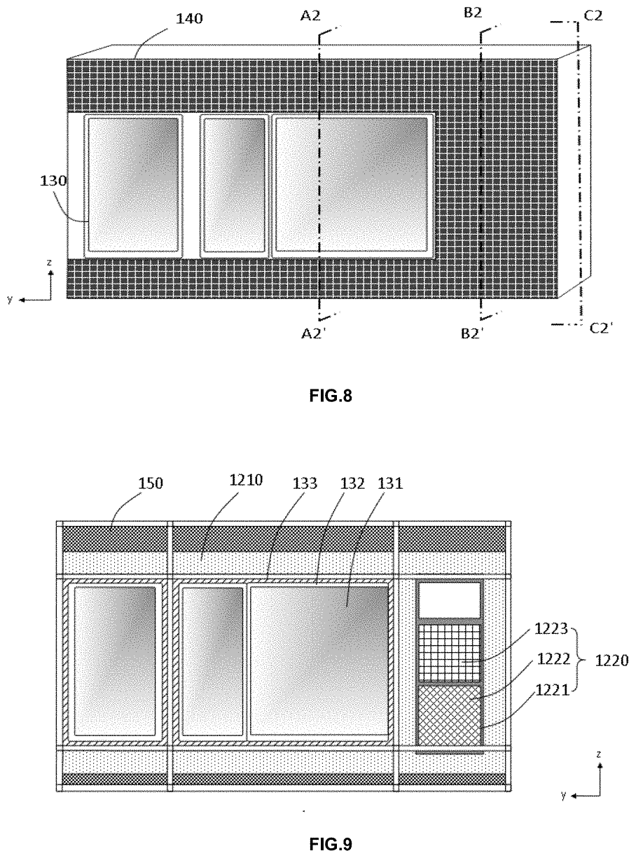

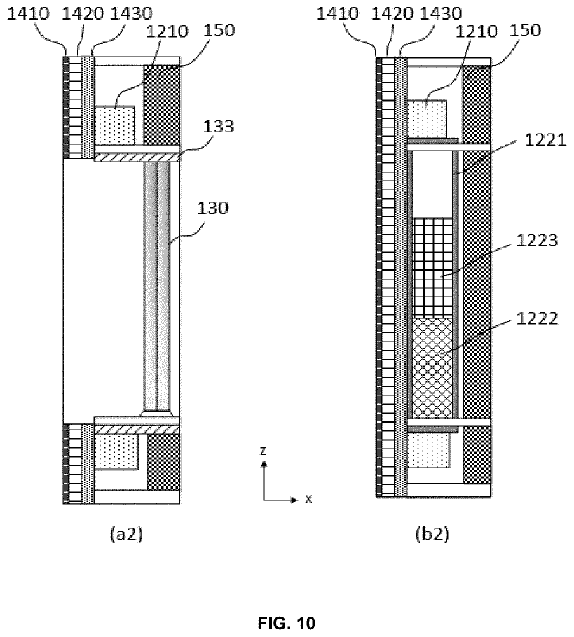

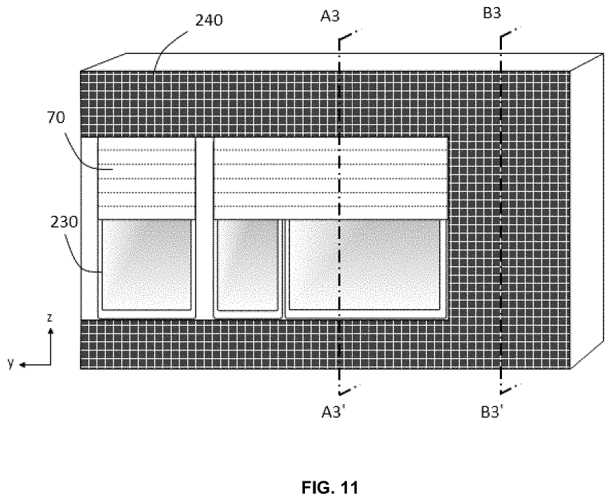

FIG. 8 is an external front view of an integrated modular smart facade system according to a second embodiment of the present invention, FIG. 9 is a sectional view taken along C2-C2′ of FIG. 8, FIG. 10(a2) is a sectional view taken along A2-A2′ of FIG. 8, and FIG. 10(b2) is a sectional view taken along B2-B2′ of FIG. 8.

The second embodiment of the present invention is identical to the first embodiment of the present invention described with reference to FIGS. 1 to 7 except that an electricity production unit 140 is located at the entirety of a wall surface of a curtain wall frame 10 that faces outwards and that a heat pump and a dehumidifier may not be included in an air treatment unit 1220.

An electricity production unit 140 according to a second embodiment of the present invention may be located at the entire outer wall surface of the curtain wall frame 10, and may not include the heat collection unit included in the first embodiment. Consequently, a heat pump 1222 and a heat exchanger 1223 may constitute an air treatment unit 1220, excluding a dehumidifier configured to use heat gas discharged from the heat pump, which is further heated by the heat collection unit. In FIGS. 9 and 10, only an elastic frame is shown as being located at an upper position adjacent to the heat exchanger 1223. However, the upper elastic frame may be excluded, and any other device may be located as needed.

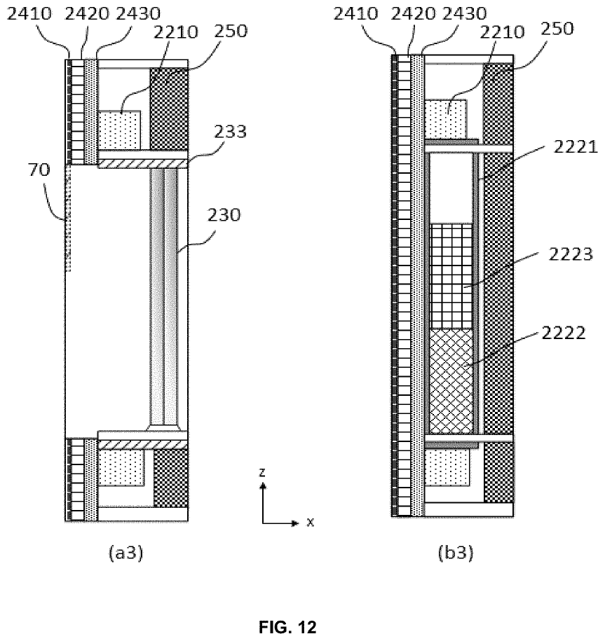

FIG. 11 is an external front view of an integrated modular smart facade system according to a third embodiment of the present invention, FIG. 12(a3) is a sectional view taken along A3-A3′ of FIG. 11, and FIG. 12(b3) is a sectional view taken along B3-B3′ of FIG. 11.

The third embodiment of the present invention is identical to the second embodiment of the present invention described with reference to FIGS. 8, 9 and 10 except that a shading unit 70 configured to cover a window unit 230 is provided.

The shading unit may be linked with the building energy management system in order to effectively control an indoor warm environment and a light environment through active control thereof.

The integrated modular smart facade system according to the third embodiment of the present invention includes a shading unit 70 configured to cover a window unit 230. The shading unit 70 may be coupled to an outer wall surface of an air conditioning unit (not shown) disposed so as to face an upper end side of the window unit 230. The shading unit 70 may include a plurality of shading louvers (not shown) disposed in parallel. The angle and location of the shading louvers may be adjusted through a sensor (not shown) configured to sense insolation conditions of external air and a controller (not shown) depending on illuminance and temperature conditions required in an inner space, whereby it is possible to adjust introduction of sunlight and/or solar heat.

Although not shown in FIGS. 1 to 12 of the present invention, each component of the integrated modular smart facade system according to the present invention includes a sensor and is connected to an artificial-intelligence-based active control system, as needed, and sensing data of each component may be monitored in real time through a separate monitoring unit. In addition, a controller may be configured to perform control necessary for the component based on the sensing data.

Although the specific details of the present invention have been described in detail, those skilled in the art will appreciate that the detailed description thereof discloses only preferred embodiments of the present invention and thus does not limit the scope of the present invention.

Accordingly, those skilled in the art will appreciate that various changes and modifications are possible, without departing from the category and the technical idea of the present invention, and it will be obvious that such changes and modifications fall within the scope of the appended claims.

### DESCRIPTION OF REFERENCE NUMERALS

1: Inner layer

2: Outer layer

3: Opening

4: Hollow portion

10: Curtain wall frame

20: Air conditioning unit

30, 130, 230: Window units

31, 131: Smart glasses

32, 132: Sashes

33, 133, 233: Anti-condensation members

40, 140: Electricity production units

50, 150: Heat insulation portions

60: Heat collection unit

70: Shading unit

210, 1210, 2210: Duct units

220, 1220, 2220: Air treatment units

221, 1221, 2221: Elastic frames

222, 1222, 2222: Heat pumps

223, 1223, 2223: Heat exchangers

224: Dehumidifier

311: Glass layer

312: Polarizing film

410, 1410, 2410: Solar energy power generation units

420, 1420, 2420: Thermoelectric element power generation units

430, 1430, 2430: Heat storage units.

What is claimed is:

1. An integrated modular smart facade system comprising:
a curtain wall frame (10);
an air conditioning unit (20) located in a hollow portion (4) of the curtain wall frame (10);
a window unit (30) located in an opening (3) of the curtain wall frame (10); and
an electricity production unit (40) located at a portion of an outer wall of the air conditioning unit (20).

2. The integrated modular smart facade system according to claim 1, wherein the electricity production unit (40) comprises one or more power generation units.

3. The integrated modular smart facade system according to claim 2, wherein each of the power generation units comprises a solar energy power generation unit (410) and/or a thermoelectric element power generation unit (420).

4. The integrated modular smart facade system according to claim 3, wherein the solar energy power generation unit (410) is of a phtovoltaic power generation type.

5. The integrated modular smart facade system according to claim 4, wherein the electricity production unit (40) further comprises a heat storage unit (430).

6. The integrated modular smart facade system according to claim 5, wherein the heat storage unit (430) is made of a phase change material comprising a thermal conductor.

7. The integrated modular smart facade system according to claim 1, further comprising:
a heat exchanger (223) and a heat pump (222) located in the air conditioning unit (20), wherein
air discharged from the electricity production unit (40) and air discharged from the heat exchanger (223) are used as a heat source of the heat pump (222).

8. The integrated modular smart facade system according to claim 7, further comprising:
an air purification and sterilization unit located in the air conditioning unit (20), wherein
the air purification and sterilization unit is connected to the heat exchanger (223) and the heat pump (222).

9. The integrated modular smart facade system according to claim 7, further comprising:
a dehumidifier (224) located in the air conditioning unit (20), wherein
the dehumidifier (224) is connected to the heat pump (222).

10. The integrated modular smart facade system according to claim 1, further comprising a heat collection unit (60) located at a portion of the outer wall of the air conditioning unit (20).
